(19) United States
(12) Patent Application Publication
(10) Pub. No.: US 2025/0038036 A1
(43) Pub. Date: Jan. 30, 2025

(54) METHOD FOR MANUFACTURING LIGHT-EMITTING DEVICE AND SEPARATION METHOD

(71) Applicant: Nichia Corporation, Anan-shi (JP)

(72) Inventor: Hiroaki KAGEYAMA, Tokushima-shi (JP)

(21) Appl. No.: 18/771,582

(22) Filed: Jul. 12, 2024

(30) Foreign Application Priority Data
Jul. 27, 2023 (JP) 2023-122673

(51) Int. Cl. H01L 21/683; B32B 43/00; H01L 33/62

(52) U.S. Cl. CPC H01L 21/6835; B32B 43/006; H01L 33/62; B32B 2310/0843; B32B 2457/00; H01L 2221/68354; H01L 2221/68368; H01L 2221/68381; H01L 2933/0066

(57) ABSTRACT

A method for manufacturing a light-emitting device includes preparing a stacked body including a substrate and a semiconductor layer on the substrate; and separating the substrate from the semiconductor layer by irradiating the stacked body with a laser light. A first region of the stacked body corresponding to an outer perimeter region of the semiconductor layer and a second region of the stacked body corresponding to a center region of the semiconductor layer are simultaneously irradiated with the laser light during the separating. An irradiation intensity of the laser light at the second region of the stacked body is greater than an irradiation intensity of the laser light at the first region of the stacked body.

### CROSS-REFERENCE TO RELATED APPLICATIONS

The present application claims priority under 35 U.S.C. § 119 to Japanese Patent Application No. 2023-122673, filed Jul. 27, 2023, the entire contents of which are hereby incorporated by reference.

### BACKGROUND

### 1. Technical Field

Embodiments described herein relate generally to a method for manufacturing a light-emitting device and a separation method.

### 2. Description of Related Art

It is known to separate a substrate from a semiconductor layer when manufacturing a light-emitting device (for example, see Japanese Patent Publication No. 2013-42191).

### SUMMARY

An embodiment is directed to a method for manufacturing a light-emitting device and a separation method in which the yield can be increased.

A method for manufacturing a light-emitting device according to an embodiment of the invention includes preparing a stacked body including a substrate and a semiconductor layer on the substrate; and separating the substrate from the semiconductor layer by irradiating the stacked body with a laser light. A first region of the stacked body corresponding to an outer perimeter region of the semiconductor layer and a second region of the stacked body corresponding to a center region of the semiconductor layer are simultaneously irradiated with the laser light during the separating. An irradiation intensity of the laser light at the second region of the stacked body is greater than an irradiation intensity of the laser light at the first region of the stacked body.

A separation method of a stacked body according to an embodiment of the invention includes separating a substrate from a semiconductor layer by irradiating the stacked body with a laser light. A first region of the stacked body corresponding to an outer perimeter region of the semiconductor layer and a second region of the stacked body corresponding to a center region of the semiconductor layer are simultaneously irradiated with the laser light during the separating. An irradiation intensity of the laser light at the second region of the stacked body is greater than an irradiation intensity of the laser light at the first region of the stacked body.

According to embodiments of the invention, a method for manufacturing a light-emitting device and a separation method can be provided in which the yield can be increased.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic plan view diagram showing a stacked body processed in a method for manufacturing a light-emitting device according to an embodiment.

FIG. 2 is a schematic cross-sectional diagram to explain a preparation process of the method for manufacturing the light-emitting device according to the embodiment.

FIG. 3 is a schematic cross-sectional diagram to explain a separation process in the method for manufacturing the light-emitting device according to the embodiment.

FIG. 4 is a schematic cross-sectional diagram to explain the separation process of the method for manufacturing the light-emitting device according to the embodiment.

FIG. 5 is a schematic cross-sectional diagram to explain a support process of the method for manufacturing the light-emitting device according to the embodiment.

FIG. 6 is a schematic cross-sectional diagram to explain a removal process of the method for manufacturing the light-emitting device according to the embodiment.

FIG. 7 is a schematic cross-sectional diagram to explain a cutting process of the method for manufacturing the light-emitting device according to the embodiment.

FIG. 8 is a schematic cross-sectional diagram to explain a mounting process of the method for manufacturing the light-emitting device according to the embodiment.

FIG. 9 is a schematic cross-sectional diagram to explain a disposing process of the method for manufacturing the light-emitting device according to the embodiment.

FIG. 10 is a schematic plan view diagram showing a mask used in the method for manufacturing the light-emitting device according to the embodiment.

FIG. 11 is a schematic enlarged plan view diagram showing a portion of the mask used in the method for manufacturing the light-emitting device according to the embodiment.

FIG. 12 is an enlarged schematic cross-sectional diagram showing a portion of the mask used in the method for manufacturing the light-emitting device according to the embodiment.

FIG. 13 is a schematic plan view diagram showing a stacked body processed in a method for manufacturing a light-emitting device according to a modification of the embodiment.

FIG. 14 is a schematic plan view diagram showing a mask used in the method for manufacturing the light-emitting device according to the modification of the embodiment.

FIG. 15 is a schematic enlarged plan view diagram showing a portion of the mask used in the method for manufacturing the light-emitting device according to the modification of the embodiment.

FIG. 16 is a schematic enlarged plan view diagram showing a portion of a mask used in a method for manufacturing a light-emitting device according to another modification of the embodiment.

FIG. 17 is a schematic enlarged plan view diagram showing a portion of a mask used in a method for manufacturing a light-emitting device according to another modification of the embodiment.

### DETAILED DESCRIPTION

Embodiments of the invention will now be described with reference to the drawings.

The drawings may be schematic or conceptual; and the relationships between the thickness and width of portions, the proportions of sizes among portions, etc., may not necessarily be the same as the actual values. The dimensions of elements or proportions thereof may be illustrated differently among drawings, even when the same element is illustrated.

In the specification and drawings, components similar to those already described are marked with the same reference numerals; and a detailed description is omitted as appropriate.

For easier understanding of the following description, the arrangements and configurations of the elements or the portions thereof are described using an XYZ orthogonal coordinate system. X-axis, Y-axis, and Z-axis are orthogonal to each other. The direction in which the X-axis extends is taken as an “X-direction”; the direction in which the Y-axis extends is taken as the “Y-direction”; and the direction in which the Z-axis extends is taken as a “Z-direction”. For easier understanding of the description, the Z-direction in the direction of the arrow is taken as “up/above”, and the opposite direction is taken as “down/below”, but these directions are independent of the direction of gravity. Viewing in an orientation along the Z-direction is called “in a plan view”. End views that show only cross sections may be used as cross-sectional views.

### Method for Manufacturing Light-Emitting Device

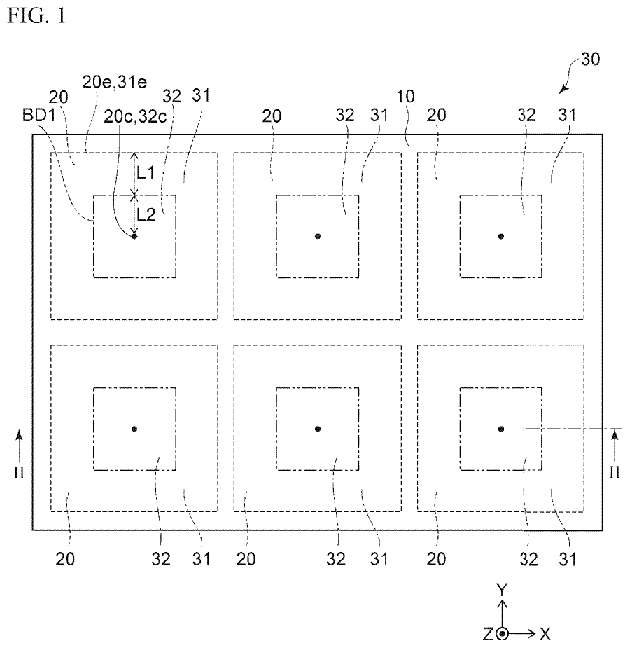

FIG. 1 is a schematic plan view diagram showing a stacked body processed in a method for manufacturing a light-emitting device according to an embodiment.

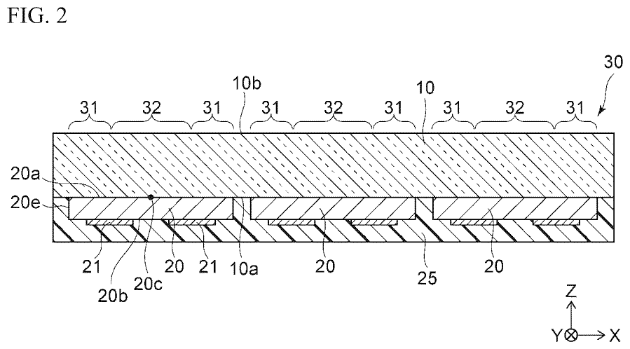

FIG. 2 is a schematic cross-sectional view diagram to explain a preparation process in the method for manufacturing the light-emitting device according to the embodiment.

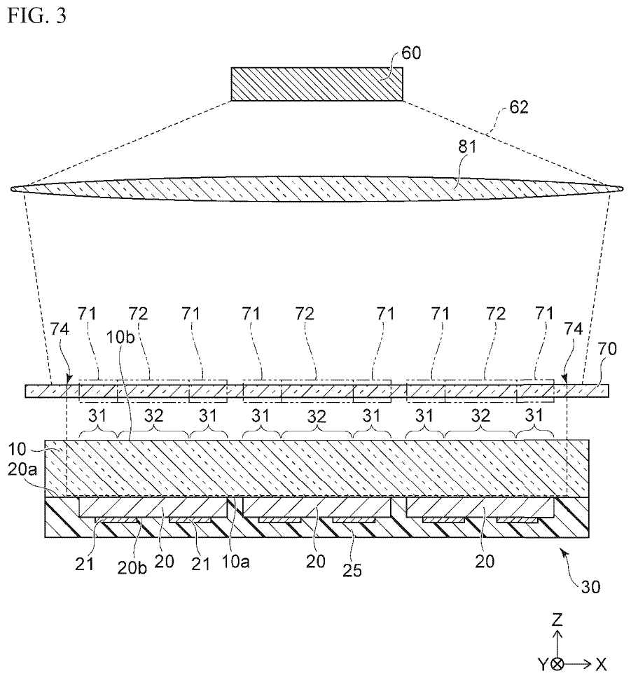

FIG. 3 is a schematic cross-sectional view diagram to explain a separation process in the method for manufacturing the light-emitting device according to the embodiment.

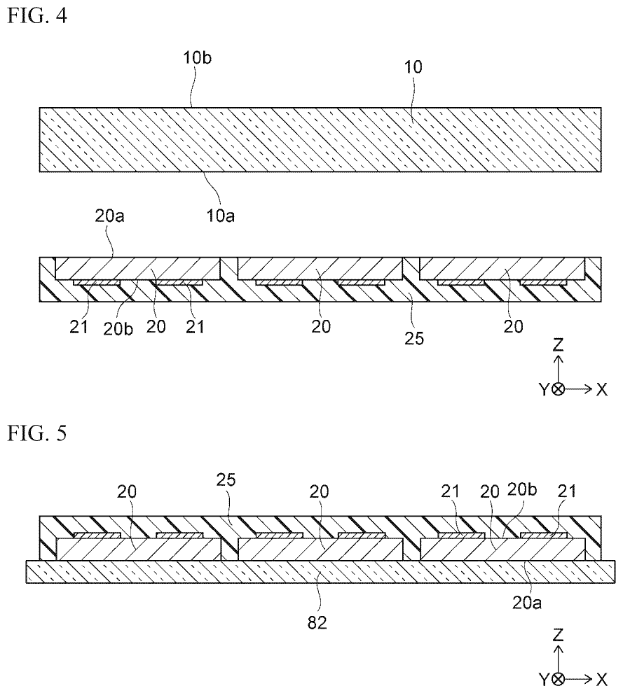

FIG. 4 is a schematic cross-sectional view diagram to explain the separation process in the method for manufacturing the light-emitting device according to the embodiment.

FIG. 5 is a schematic cross-sectional view diagram to explain a support process in the method for manufacturing the light-emitting device according to the embodiment.

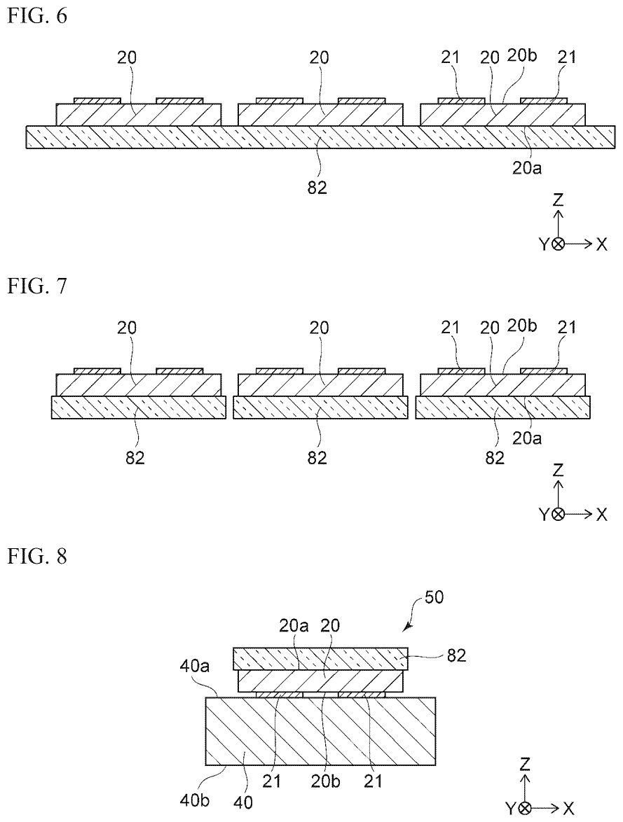

FIG. 6 is a schematic cross-sectional view diagram to explain a removal process in the method for manufacturing the light-emitting device according to the embodiment.

FIG. 7 is a schematic cross-sectional view diagram to explain a cutting process in the method for manufacturing the light-emitting device according to the embodiment.

FIG. 8 is a schematic cross-sectional view diagram to explain a mounting process in the method for manufacturing the light-emitting device according to the embodiment.

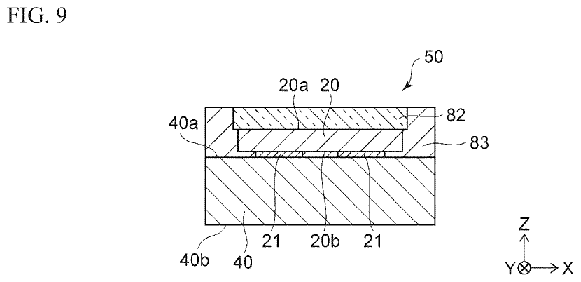

FIG. 9 is a schematic cross-sectional view diagram to explain a disposing process in the method for manufacturing the light-emitting device according to the embodiment.

FIG. 2 schematically illustrates a cross-sectional view along line II-II shown in FIG. 1. FIGS. 3 to 9 schematically illustrate cross-sectional views corresponding to the position of line II-II of FIG. 1 in each process.

As shown in FIGS. 1 to 4, the method for manufacturing the light-emitting device according to the embodiment includes a preparation process and a separation process. The separation process is performed after the preparation process.

### Preparation Process

As shown in FIGS. 1 and 2, a stacked body 30 is prepared in the preparation process. The stacked body 30 includes a substrate 10, and a semiconductor layer 20 stacked on the substrate 10. The stacked body 30 may be purchased or may be manufactured. When the stacked body 30 is manufactured, the stacked body 30 can be made by stacking the semiconductor layer 20 on the substrate 10. A first surface 20a of the semiconductor layer 20 of the stacked body 30 faces a first surface 10a of the substrate 10. The stacked body 30 can include an electrode 21 at a second surface 20b side; and the second surface 20b is positioned at the side opposite to the first surface 20a of the semiconductor layer 20. In the example shown in FIG. 2, the stacked body 30 includes a coating layer 25 covering the second surface 20b of the semiconductor layer 20 and the first surface 10a of the substrate 10.

The stacked body 30 includes a plurality of outer perimeter regions 31 and a plurality of central regions 32 in a plan view (e.g., FIG. 1). Each central region 32 is positioned inside the corresponding outer perimeter region 31. The outer perimeter region 31 and the central region 32 may be named according to their location relative to the corresponding semiconductor layers 20 and may not be a perimeter region and a central region of the stacked body 30 itself. Hereinafter, the outer perimeter region 31 and the central region 32 may be referred to as a first region and a second region, respectively. As shown in FIG. 1, the outer perimeter region 31 and the central region 32 therein are partitioned by a boundary BD1 which is a virtual line. An outer perimeter edge 31e of the outer perimeter region 31 overlaps an outer perimeter edge 20e of the semiconductor layer 20 in the plan view. A center 32c of the central region 32 overlaps a center 20c of the semiconductor layer 20 in the plan view. The outer perimeter region 31 and the central region 32 therein correspond to an outer perimeter part (i.e., the outer part including the outer perimeter edge 20e) and the central part (i.e., the inner part including the center 20c) of the semiconductor layer 20 in the plan view. In the example shown in FIG. 1, the exterior shape of the semiconductor layer 20 is rectangular. The exterior shape of the semiconductor layer 20 is not limited to rectangular and may be polygonal other than rectangular, or may be circular. The corners of the polygon may or may not be recessed. The sides of the polygon may be straight lines or curves.

In the example shown in FIG. 1, the exterior shape of each outer perimeter region 31 is rectangular. Similarly, the exterior shape of each central region 32 (i.e., the exterior shape defined by the boundary BD1 which is a virtual line) is rectangular. In the example shown in FIG. 1, the boundary BD1 is positioned between the outer perimeter edge 31e of the outer perimeter region 31 and the center 32c of the central region 32 therein. For example, a distance L1 between the boundary BD1 and the outer perimeter edge 31e of the outer perimeter region 31 is equal to a distance L2 between the boundary BD1 and the center 32c of the central region 32. The distance L1 may be less than the distance L2 in a specific implementation or may be greater than the distance L2 in another specific implementation. The exterior shape of each outer perimeter region 31 matches the exterior shape of the semiconductor layer 20. The exterior shape of the central region 32 can be shapes such as those described above for the exterior shape of the semiconductor layer 20. The exterior shape of the outer perimeter region 31 may be the same as or different from the exterior shape of the central region 32. This is similar for the exterior shape of an intermediate region 33, which is described below.

### Separation Process

In the separation process as shown in FIGS. 3 and 4, the substrate 10 is separated from the semiconductor layer 20 by irradiating the stacked body 30 with a laser light 62 from a laser light irradiation device 60. The laser light 62 is incident from a second surface 10b side positioned at the side opposite to the first surface 10a of the substrate 10, passes through the substrate 10, and reaches the vicinity of the interface between the substrate 10 and the semiconductor layer 20 (i.e., the contact surface between the first surface 10a of the substrate 10 and the first surface 20a of the semiconductor layer 20). When the semiconductor layer 20 includes gallium nitride (GaN), the substrate 10 can be separated from the semiconductor layer 20 by the gallium nitride present at the vicinity of the interface between the semiconductor layer 20 and the substrate 10 being decomposed into gallium metal and nitrogen gas by the laser light 62.

In the separation process, irradiation with the laser light 62 is performed simultaneously on the central region 32 and the outer perimeter region 31 therein. That is, in the separation process, the irradiation with the laser light 62 is performed on both the central region 32 and the outer perimeter region 31 by one irradiation with the laser light 62. When the laser light 62 is pulsated, one set from the start to the end of irradiation of a single prescribed pulse width is considered to be one irradiation with the laser light 62. In the separation process, the irradiation with the laser light 62 is performed on the entire central region 32 and the entire outer perimeter region 31 therein.

In the separation process, the irradiation intensity of the laser light 62 at the central region 32 is set to be greater than the irradiation intensity of the laser light 62 at the outer perimeter region 31 corresponding thereto. The irradiation intensity is expressed as energy per unit area (J/cm²). The irradiation intensity of the laser light 62 at the central region 32 is, for example, not less than 1.0 J/cm² and not more than 1.2 J/cm². The irradiation intensity of the laser light 62 at the outer perimeter region 31 corresponding thereto is, for example, not less than 0.8 J/cm² and not more than 1.0 J/cm².

When the irradiation of the same irradiation amount of the laser light 62 is performed on the outer perimeter region 31 and the central region 32 therein of the stacked body 30, there are cases where the outer perimeter region 31 separates before the central region 32 separates. When the separation of the outer perimeter region 31 and the separation of the central region 32 occur at different timing, the semiconductor layer 20 may distort, and delamination defects such as cracks of the semiconductor layer 20 may occur. The reasons are considered to be as follows.

For example, when the stacked body 30 is manufactured by forming the semiconductor layer 20 including gallium nitride, which has a lower thermal expansion coefficient than sapphire, on the substrate 10 made of sapphire, it is necessary to form the semiconductor layer 20 in a state in which the substrate 10 is heated to a high temperature. Here, the “high temperature” refers to about 1,000° C. When returning from the high temperature to room temperature after forming the semiconductor layer 20, the contraction of the substrate 10 is greater than the contraction of the semiconductor layer 20, and so the stacked body 30 may have a shape in which the center of the substrate 10 is concave toward the first surface 10a side. On the other hand, after the separation of the substrate 10, since the electrode 21 (e.g., gold) has a higher thermal expansion coefficient than gallium nitride, the thermal expansion coefficient difference between the semiconductor layer 20 and the electrode 21 causes the semiconductor layer 20 to have a shape in which the center of the semiconductor layer 20 is concave toward the first surface 20a side. Thus, the directions of the concavity of the semiconductor layer 20 before and after the separation of the substrate 10 are opposite, and so the part corresponding to the outer perimeter region 31 has a greater stress change than the part corresponding to the central region 32; and the residual stress of the outer perimeter region 31 is greater than the residual stress of the central region 32. Here, the “residual stress” refers to the stress remaining after the irradiation with the laser light 62. It is considered that, as a result, the outer perimeter region 31 separates before the central region 32 separates when the laser light irradiation of the same irradiation amount is performed on the outer perimeter region 31 and the central region 32 of the stacked body 30.

In contrast, by setting the irradiation intensity of the laser light 62 at the central region 32 to be greater than the irradiation intensity of the laser light 62 at the outer perimeter region 31, the separation of the central region 32 can be earlier, and the separation of the outer perimeter region 31 can be relatively delayed. As a result, the timing difference between the separation of the outer perimeter region 31 and the separation of the central region 32 can be reduced. As a result, the occurrence of delamination defects such as cracks of the semiconductor layer 20 can be reduced, and the yield can be increased. The timing difference between the separation of the outer perimeter region 31 and the separation of the central region 32 can be eliminated, and the occurrence of delamination defects can be further reduced by simultaneously performing the separation of the outer perimeter region 31 and the separation of the central region 32 therein.

Examples of techniques for setting the irradiation intensity of the laser light 62 at the central region 32 to be greater than the irradiation intensity of the laser light 62 at the outer perimeter region 31 include use of a mask. In the separation process according to the embodiment, a mask 70 is located at the side of the stacked body 30 on which the irradiation with the laser light 62 is performed as shown in FIG. 3. In other words, in the stacked body 30 in which the substrate 10 is positioned on the semiconductor layer 20, the mask 70 is located above (in the Z-direction of) the stacked body 30. The mask 70 includes a plurality of first areas 71 corresponding to the outer perimeter regions 31, and a plurality of second areas 72 corresponding to the central regions 32. The mask 70 is positioned so that the first areas 71 overlap the outer perimeter regions 31 in a plan view, and the second areas 72 overlap the central regions 32 in the plan view.

In the separation process of the example shown in FIGS. 1 to 9, the irradiation with the laser light 62 of the same irradiation intensity is performed simultaneously on the first and second areas 71 and 72. The irradiation intensity of the laser light 62 transmitted through the second area 72 and casted on the central region 32 is set to be greater than the irradiation intensity of the laser light 62 transmitted through the first area 71 and casted on the outer perimeter region 31.

Specifically, the level of the light shielding in the first area 71 is set to be greater than the level of the light shielding in the second area 72 by using the mask 70, so that the irradiation intensity of the laser light 62 transmitted through the second area 72 and casted on the central region 32 can be set to be greater than the irradiation intensity of the laser light 62 transmitted through the first area 71 and casted on the outer perimeter region 31.

The technique for setting the irradiation intensity of the laser light 62 casted on the central region 32 to be greater than the irradiation intensity of the laser light 62 casted on the outer perimeter region 31 is not limited to the use of the mask 70. Examples include, for example, forming a structure body including a plurality of substructures such as protrusions and/or recesses (hereinbelow, also called simply the “structure body”) in the second surface 10b of the substrate 10. By forming the structure body, the laser light 62 that travels to the substrate 10 is scattered by the structure body; therefore, compared to when the structure body is not formed, the irradiation intensity of the laser light 62 at the vicinity of the interface between the substrate 10 and the semiconductor layer 20 is less. By adjusting the density, size, etc., of the substructures, the irradiation intensity of the laser light 62 at the vicinity of the interface between the substrate 10 and the semiconductor layer 20 can be adjusted. Specifically, as a first example, the density of the substructures in the part of the second surface 10b of the substrate 10 corresponding to the outer perimeter region 31 can be set to be greater than the density of the substructures in the part of the second surface 10b of the substrate 10 corresponding to the central region 32. The density is the ratio of the area of the structure body to the area of the entire part corresponding to the outer perimeter region 31 or the central region 32. As a second example, the size of the substructures in the part of the second surface 10b of the substrate 10 corresponding to the outer perimeter region 31 can be set to be greater than the size of the substructures in the part of the second surface 10b of the substrate 10 corresponding to the central region 32. As a third example, the structure body can be formed in only the outer perimeter region 31 of the second surface 10b of the substrate 10.

When the substructures are formed, a flat surface may be provided between the adjacent substructures, or the substructures may be connected to each other without a flat surface. The shape of each substructure is, for example, a pyramid shape such as a triangular pyramid or the like, a column shape such as a quadrilateral pyramid or the like, a dome shape such as a hemisphere, etc. When the semiconductor layer 20 is rectangular with a size of 1 mmxl mm in a plan view, the maximum width of the structure body in the plan view is, for example, not less than 1 μm and not more than 2 μm; and the height of the structure body is, for example, not less than 1 μm and not more than 2 μm. For example, the structure body is formed by etching the substrate 10. In such a case, the structure body is included as a portion of the substrate 10. When the substructures are formed, the size and/or height of each substructure may be the same or different. The structure body may be a rough surface.

As the semiconductor layer that is stacked on the substrate 10, the stacked body 30 may include multiple semiconductor layers 20 that are separated from each other. In the stacked body 30 of the example shown in FIGS. 1 to 9, six semiconductor layers 20 are arranged in a matrix configuration on one substrate 10. The six semiconductor layers 20 include three semiconductor layers 20 arranged in the X-direction and two semiconductor layers 20 arranged in the Y-direction. The stacked body 30 includes the outer perimeter region 31 and the central region 32 corresponding to each semiconductor layer 20.

In the separation process of the example shown in FIGS. 1 to 9, the irradiation with the laser light 62 is performed simultaneously on a region of the stacked body 30 including the multiple semiconductor layers 20. As a result, the substrate 10 can be separated simultaneously from the multiple semiconductor layers 20.

For example, when the semiconductor layer 20 including gallium nitride is irradiated with the laser light 62, the gallium nitride that is present at the vicinity of the interface between the semiconductor layer 20 and the substrate 10 is decomposed into gallium metal and nitrogen gas by the laser light 62. At this time, the nitrogen gas can be released outside because the opposing side surfaces of adjacent semiconductor layers 20 are open to the outside. Accordingly, compared to when the semiconductor layers 20 are not separated from each other (i.e., when one semiconductor layer 20 is stacked on the substrate 10), the occurrence of expansion and/or cracks of the semiconductor layer 20 due to the nitrogen gas can be reduced.

In the example shown in FIGS. 1 to 9, the stacked body 30 includes the multiple semiconductor layers 20; and the irradiation with the laser light 62 is performed simultaneously on the multiple semiconductor layers 20. However, the irradiation is not limited thereto; and the irradiation with the laser light 62 may be performed individually for each semiconductor layer 20. The stacked body 30 is not limited to including the multiple semiconductor layers 20, and may include only one semiconductor layer 20.

The substrate 10, the semiconductor layer 20, and the coating layer 25 included in the stacked body 30 will now be described.

### Substrate

The substrate 10 is a member on which the semiconductor layer 20 is stacked. The substrate 10 is, for example, configured to transmit the laser light 62. The substrate 10 includes, for example, at least one of sapphire or glass. The substrate 10 has, for example, a flat plate shape.

### Semiconductor Layer

The semiconductor layer 20 includes, for example, an n-type semiconductor layer, a p-type semiconductor layer, and a light-emitting layer. The light-emitting layer is positioned between the n-type semiconductor layer and the p-type semiconductor layer. The light-emitting layer may have a structure such as a double heterojunction, single quantum well (SQW), etc., or may have a structure of one light-emitting layer group such as a multi-quantum well (MQW). The light emission peak wavelength of the light-emitting layer can be appropriately selected according to the purpose. For example, the light-emitting layer can be configured to emit visible light or ultraviolet light. The semiconductor stacked body that includes such a light-emitting layer includes, for example, all of the compositions of semiconductors of the chemical formula InₓAl_{y}Ga_{1-x-y}N (0≤x, 0≤y, and x+y≤1) for which the composition ratios x and y are changed within the ranges respectively.

The semiconductor layer 20 may have a structure including one or more light-emitting layers between the n-type semiconductor layer and the p-type semiconductor layer, or may have a structure in which a structure that includes an n-type semiconductor layer, a light-emitting layer, and a p-type semiconductor layer in this order is multiple repeated. When the semiconductor layer 20 includes multiple light-emitting layers, the multiple light-emitting layers may include light-emitting layers having different light emission peak wavelengths, or may include light-emitting layers having the same light emission peak wavelength. The light emission peak wavelength being the same also includes cases where the difference is within ±10 nm. The combination of the light emission peak wavelengths between the multiple light-emitting layers can be selected as appropriate. For example, when the semiconductor layer 20 includes two light-emitting layers, the light-emitting layers can be selected in combinations of blue light and blue light, green light and green light, red light and red light, ultraviolet light and ultraviolet light, blue light and ultraviolet light, blue light and green light, blue light and red light, green light and red light, etc. Each light-emitting layer may include multiple active layers having different light emission peak wavelengths, or multiple active layers having the same light emission peak wavelength.

The semiconductor layer 20 is, for example, rectangular in a plan view. It is favorable for the length of one side of the semiconductor layer 20 in the plan view to be not less than 200 μm and not more than 2,000 μm. Within this range, the occurrence of delamination defects such as cracks of the semiconductor layer 20 can be further reduced even when warp of the semiconductor layer 20 occurs.

### Coating Layer

The coating layer 25 is a member for holding the semiconductor layer 20. When the stacked body 30 includes the semiconductor layer 20 in multiple, the coating layer 25 can cover the side surfaces and the second surfaces 20b of the semiconductor layers 20, and can connect adjacent semiconductor layers 20. As a result, the coating layer 25 can hold the semiconductor layers 20 when separating the substrate 10 from the semiconductor layers 20. For example, a polyimide resin can be used as the material of the coating layer 25. In the preparation process, the stacked body 30 can be located on a support body with the coating layer 25 interposed. In such a case, the coating layer 25 can function also as a bonding member that bonds the support body and the semiconductor layer 20 of the stacked body 30. The support body can be used to reduce the warp of the semiconductor layer 20 occurring when the substrate 10 is separated from the semiconductor layer 20. For example, sapphire can be used as the support body.

### Laser Light

The laser light irradiation device 60 can employ a gas laser or a solid-state laser. For example, an excimer laser can be used as the gas laser. For example, the laser light irradiation device 60 radiates pulsed laser light 62. In such a case, the pulse width is, for example, 20 nsec. The light emission peak wavelength of the laser light 62 is, for example, 248 nm. For example, the laser light 62 can be emitted from the laser light irradiation device 60, and can reach the mask 70 by passing through a lens 81. A top-hat laser beam in which the irradiation intensity distribution of the laser light is substantially uniform can be used as the laser light 62.

### Support Process

The method for manufacturing the light-emitting device according to the embodiment can further include a support process. The support process is performed after the separation process.

In the support process as shown in FIG. 5, a light-transmitting layer 82 is disposed on the surface (i.e., the first surface 20a) of the semiconductor layer 20 at the side from which the substrate 10 was separated. The light-transmitting layer 82 includes, for example, a fluorescer. For example, the light-transmitting layer 82 is disposed on the first surface 20a of the semiconductor layer with the bonding member interposed. The light-transmitting layer 82 has, for example, a flat plate shape.

### Removal Process

The method for manufacturing the light-emitting device according to the embodiment can further include a removal process. The removal process is performed after the support process.

As shown in FIG. 6, the coating layer 25 is removed in the removal process. As a result, the electrode 21 that is located at the second surface 20b side of each semiconductor layer 20 is exposed.

### Cutting Process

The method for manufacturing the light-emitting device according to the embodiment can further include a cutting process. The cutting process is performed after the removal process.

As shown in FIG. 7, the light-transmitting layer 82 is cut in the cutting process. When cutting the light-transmitting layer 82, any position between the adjacent semiconductor layers 20 can be cut. For example, the center between the adjacent semiconductor layers 20 can be cut. Multiple semiconductor layers 20 on each of which the light-transmitting layer 82 is disposed can be obtained by cutting the light-transmitting layer 82.

### Mounting Process

The method for manufacturing the light-emitting device according to the embodiment can further include a mounting process. The mounting process is performed after at least the separation process. For example, the mounting process is performed after the cutting process.

In the mounting process as shown in FIG. 8, the semiconductor layer 20 is mounted so that the surface (i.e., the second surface 20b) at the side opposite to the surface (i.e., the first surface 20a) of the semiconductor layer 20 that was separated from the substrate 10 faces an upper surface 40a of a wiring substrate 40. At this time, a conductive member can be disposed between the electrode 21 and the wiring substrate 40 to electrically connect the wiring substrate 40 and the electrode 21 located at the second surface 20b of the semiconductor layer 20. A light-emitting device 50 is manufactured by mounting the semiconductor layer 20 separated from the substrate 10 to the wiring substrate 40. In the mounting process shown in FIG. 8, the semiconductor layer 20 on which the light-transmitting layer 82 is disposed is mounted to the wiring substrate 40. In the example shown in FIG. 8, one semiconductor layer 20 is mounted to the wiring substrate 40. However, the configuration is not limited thereto; multiple semiconductor layers 20 may be mounted to the wiring substrate 40. The wiring substrate 40 includes the upper surface 40a and a lower surface 40b.

### Disposing Process

The method for manufacturing the light-emitting device according to the embodiment can further include a disposing process. The disposing process is performed after the mounting process.

In the disposing process as shown in FIG. 9, a light-reflective member 83 is disposed to cover the side surfaces of the light-transmitting layer 82 and the side surfaces of the semiconductor layer 20. The light-reflective member 83 may be configured to include an organic material, may be configured to include an inorganic material, or may be configured to include both an organic material and an inorganic material. A resin can be used as the organic material. For example, a mixture that includes silica, boron nitride, and an alkali metal can be used as the inorganic material.

### Wiring Substrate

The wiring substrate 40 includes, for example, a base member, and a wiring part located on the base member. The wiring substrate 40 has, for example, a flat plate shape.

The mask 70 will now be described in detail.

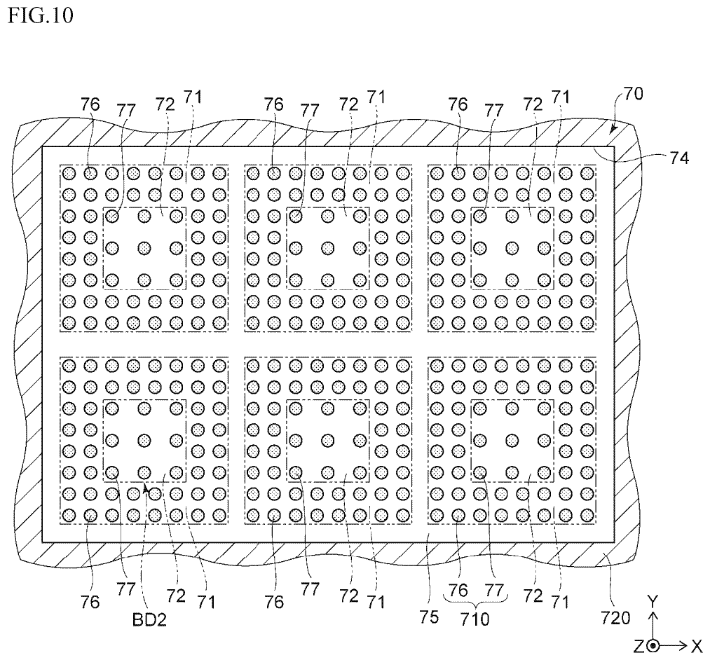

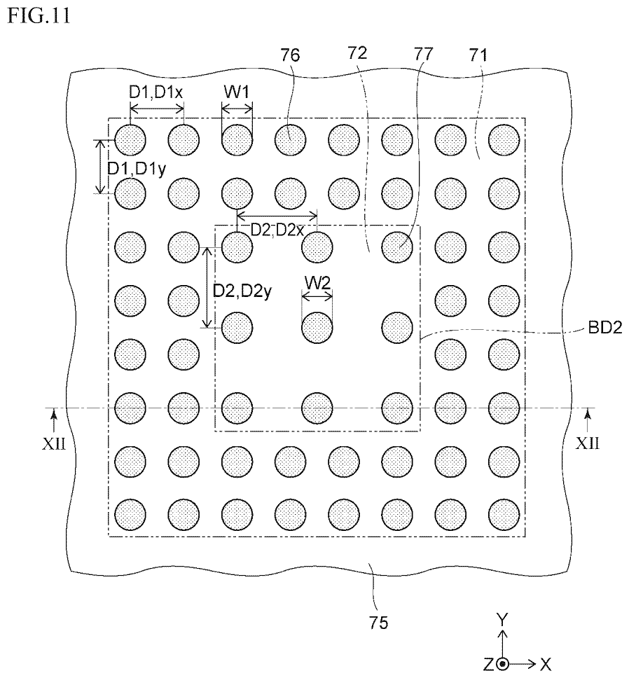

FIG. 10 is a schematic plan view diagram showing a mask used in the method for manufacturing the light-emitting device according to the embodiment.

FIG. 11 is a schematic enlarged plan view diagram showing a portion of the mask used in the method for manufacturing the light-emitting device according to the embodiment.

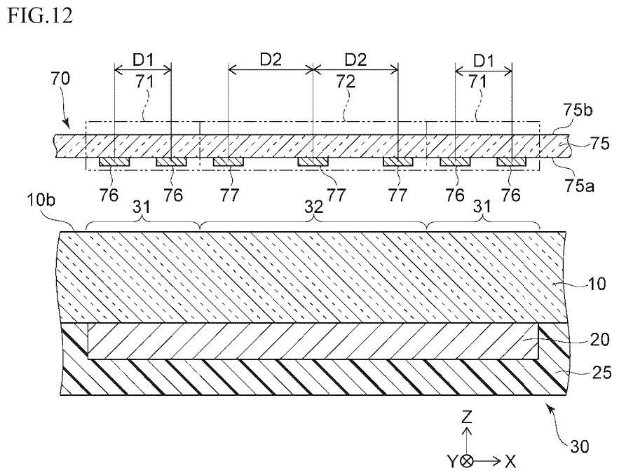

FIG. 12 is an enlarged schematic cross-sectional diagram showing a portion of the mask used in the method for manufacturing the light-emitting device according to the embodiment.

Apart of the mask illustrated in FIG. 10 is enlarged in FIG. 11. FIG. 12 schematically illustrates a cross-sectional view along line XII-XII shown in FIG. 11.

The mask 70 includes the plurality of first areas 71 corresponding to the outer perimeter regions 31 of the stacked body 30, and the plurality of second areas 72 corresponding to the central regions 32 of the stacked body 30. The first area 71 and the corresponding second area 72 are partitioned by a boundary BD2 which is a virtual line. The mask 70 includes one or more first light-shielding structures 76 that are positioned in each first area 71 and shield the laser light 62. In the example shown in FIGS. 10 to 12, the mask 70 includes multiple first light-shielding structures 76 that are positioned each first area 71 and shield the laser light 62, and multiple second light-shielding structures 77 that are positioned in each second area 72 and shield the laser light 62. Even when using a mask that includes the first and second light-shielding structures 76 and 77, the irradiation with the laser light 62 is performed in the regions of the outer perimeter regions 31 and the central regions 32 positioned directly under the first light-shielding structures 76 and the second light-shielding structures 77. This is because the light that passes between adjacent first light-shielding structures 76 and adjacent second light-shielding structures 77 can spread to the regions positioned directly thereunder. Also, when the first light-shielding structures 76 and the second light-shielding structures do not completely shield the laser light 62, the irradiation with the laser light 62 is performed on the regions positioned directly under the first and second light-shielding structures 76 and 77 by a passing through the first and second light-shielding structures 76 and 77.

In the example shown in FIGS. 10 to 12, the exterior shape of the first area 71 is rectangular in a plan view. Similarly, the exterior shape of the second area 72 (i.e., the exterior shape defined by the boundary BD2 which is a virtual line) is rectangular. The exterior shape of the first area 71 matches the exterior shape of the outer perimeter region 31. The exterior shape of the second area 72 matches the exterior shape of the central region 32. In other words, the exterior shape defined by the boundary BD2 which is a virtual line matches the exterior shape defined by the boundary BD1 which is a virtual line.

The exterior shape of the second area 72 is not limited to rectangular and may be, for example, a shape in which the four corners of the rectangle are recessed. The exterior shapes of the first and second areas 71 and 72 are not limited to rectangular and may be polygonal other than rectangular, or may be circular. The corners of the polygon may or may not be recessed. The sides of the polygon may be straight lines or curves. The exterior shape of the first area 71 may be the same as or different from the exterior shape of the second area 72. This is similar for the exterior shape of a third area 73 described below.

In the example shown in FIGS. 10 to 12, the first light-shielding structures 76 and the second light-shielding structures 77 are each regularly arranged in a matrix configuration along the X-direction and the Y-direction in a plan view. The first light-shielding structures 76 and the second light-shielding structures 77 may be arranged in a staggered configuration in the plan view. The arrangement of the first light-shielding structures 76 may be the same as or different from the arrangement of the second light-shielding structures 77.

In the example shown in FIGS. 10 to 12, the first light-shielding structure 76 and the second light-shielding structure 77 have the same size (e.g., the same footprint) in the plan view. That is, a width W1 of the first light-shielding structure 76 in the plan view is equal to a width W2 of the second light-shielding structure 77 in the plan view; and the area of the first light-shielding structure 76 in the plan view is the same as the area of the second light-shielding structure 77 in the plan view.

As shown in FIG. 11, the width W1 and the width W2 are the maximum X-direction widths. It is favorable for the widths W1 and W2 to be, for example, not less than 1 μm and not more than 3 μm. It is favorable for the widths W1 and W2 to be, for example, not less than 1/400 times and not more than 1/100 times the exterior shape of the semiconductor layer 20.

As long as the irradiation intensity of the laser light 62 at the central region 32 can be set to be greater than the irradiation intensity of the laser light 62 at the outer perimeter region 31 therearound, the first light-shielding structure 76 and the second light-shielding structure 77 are not limited to having the same size in the plan view, and may have different sizes in the plan view. For example, the first light-shielding structure 76 may be larger than the second light-shielding structure 77 or smaller than the second light-shielding structure 77 in the plan view.

In the example shown in FIGS. 10 to 12, the first light-shielding structure 76 and the second light-shielding structure 77 are circular in the plan view. The shapes of the first and second light-shielding structures 76 and 77 in the plan view are not limited to circular and may be rectangular, etc. The first light-shielding structure 76 and the second light-shielding structure 77 may have the same shape or different shapes in the plan view.

In the example shown in FIGS. 10 to 12, the first light-shielding structures 76 are arranged at uniform spacing in the X-direction. That is, a spacing D1x in the X-direction of the first light-shielding structures 76 is constant. In the example shown in FIGS. 10 to 12, the first light-shielding structures 76 are arranged at uniform spacing in the Y-direction. That is, a spacing D1y in the Y-direction of the first light-shielding structures 76 is constant. In the example shown in FIGS. 10 to 12, the spacing D1x is the same as the spacing D1y. When the spacing D1x and the spacing D1y are constant, unevenness of the irradiation intensity at the outer perimeter region 31 can be reduced. The spacing D1x may not be constant. The spacing D1y may not be constant. The spacing D1x may be different from the spacing D1y. For example, the average value of the spacings D1x and D1y is taken as a spacing D1 of the adjacent first light-shielding structures 76. Here, “spacing” refers to the distance between the centers of the adjacent first light-shielding structures 76. The spacing D1 is, for example, not less than 4 μm and not more than 6 μm. The spacing D1 is, for example, not less than 1/300 times and not more than 1/200 times the exterior shape of the semiconductor layer 20.

In the example shown in FIGS. 10 to 12, the second light-shielding structures 77 are arranged at uniform spacing in the X-direction. That is, a spacing D2x in the X-direction of the second light-shielding structures 77 is constant. In the example shown in FIGS. 10 to 12, the second light-shielding structures 77 are arranged at uniform spacing in the Y-direction. That is, a spacing D2y in the Y-direction of the second light-shielding structures 77 is constant. In the example shown in FIGS. 10 to 12, the spacing D2x is the same as the spacing D2y. When the spacing D2x and the spacing D2y are constant, unevenness of the irradiation intensity at the central region 32 can be reduced. The spacing D2x may not be constant. The spacing D2y may not be constant. The spacing D2x may be different from the spacing D2y. For example, the average value of the spacings D2x and D2y is taken as a spacing D2 of the adjacent second light-shielding structures 77. Here, “spacing” refers to the distance between the centers of the adjacent second light-shielding structures 77. The spacing D2 is, for example, not less than 6 μm and not more than 10 μm. The spacing D2 is, for example, not less than 1/200 times and not more than 1/100 times the exterior shape of the semiconductor layer 20.

In the example shown in FIGS. 10 to 12, the spacing D2 is greater than the spacing D1. In the example shown in FIGS. 10 to 12, the density of the second light-shielding structures 77 in the second area 72 is less than the density of the first light-shielding structures 76 in the first area 71. The density is the ratio of the area of the light-shielding structures to the area of each entire region. As a result, the level of the light shielding in the first area 71 can be set to be greater than the level of the light shielding in the second area 72; and the irradiation intensity of the laser light 62 transmitted through the second area 72 and casted on the central region 32 can be set to be greater than the irradiation intensity of the laser light 62 transmitted through the first area 71 and casted on the outer perimeter region 31.

In the example shown in FIGS. 10 to 12, the mask 70 includes a light-transmitting member 75, and the first light-shielding structures 76 and the second light-shielding structures 77 located at the light-transmitting member 75. The light-transmitting member 75 includes a first surface 75a facing the stacked body 30, and a second surface 75b positioned at the side opposite to the first surface 75a. The first light-shielding structures 76 can be located in at least one of the first surface 75a or the second surface 75b. The second light-shielding structures 77 can be located in at least one of the first surface 75a or the second surface 75b. In the example shown in FIGS. 10 to 12, the first light-shielding structures 76 and the second light-shielding structures 77 are located at the first surface 75a. As a result, the light that has passed between the adjacent first light-shielding structures 76 and between the adjacent second light-shielding structures 77 does not pass through the light-transmitting member 75, and so the light is easily emitted in the desired direction compared to when the first light-shielding structures 76 and the second light-shielding structures 77 are located at the second surface 75b.

In the example shown in FIG. 10, the mask 70 includes an inner light-shielding part 710 that includes the first and second light-shielding structures 76 and 77, and an outer light-shielding part 720 that includes an opening 74. The inner light-shielding part 710 is located inside the opening 74. Among the laser light emitted from the laser light irradiation device 60, the mask 70 shields the laser light that is casted on the outer light-shielding part 720 and the light that is casted on the inner light-shielding part 710. When the laser light has a top-hat irradiation intensity distribution, the irradiation intensity distribution includes a region at the center in which the irradiation intensity is substantially uniform (hereinbelow, also called the “region A”), and regions at the two end portions having lower irradiation intensities than the center (hereinbelow, also called the “region B”). By irradiating the region A inside the opening 74 of the mask 70 with the laser light (i.e., by not irradiating the region B inside the opening 74 of the mask 70 with the laser light), the irradiation intensity inside the opening 74 of the mask 70 can be substantially uniform. As a result, unevenness of the irradiation intensity inside the opening 74 can be reduced.

The transmittance of the outer light-shielding part 720 of the mask 70 with respect to the laser light is, for example, 0%. As a result, the light that is emitted from the laser light irradiation device 60 can be shielded completely by the outer light-shielding part 720 of the mask 70, and can be transmitted only inside the opening 74.

In the mask 70, similarly to the region inside the opening 74, the region outside the opening 74 can include the light-transmitting member 75 and the outer light-shielding part 720 at the first surface 75a and/or the second surface 75b of the light-transmitting member 75. The outer light-shielding part 720 may be the same material as the first and second light-shielding structures 76 and 77, or may be a different material.

The mask 70 is not limited to using the light-transmitting member 75 as a base member and providing the first and second light-shielding structures 76 and 77 at the light-transmitting member 75; a light-shielding member may be used as a base member, and light-transmitting structures such as holes, etc., may be provided in the light-shielding member. In such a case, the light-shielding member corresponds to the first and second light-shielding structures.

### Light-Transmitting Member

The light-transmitting member 75 is a member supporting the first light-shielding structures 76 and the second light-shielding structures 77. The light-transmitting member 75 is configured to transmit the laser light 62. It is sufficient for the light-transmitting member 75 to be able to transmit at least a portion of the laser light 62. The transmittance of the light-transmitting member 75 for the laser light 62 is, for example, 90%. The light-transmitting member 75 can include, for example, glass. The light-transmitting member 75 has, for example, a flat plate shape.

### First Light-Shielding Structure and Second Light-Shielding Structure

The first light-shielding structure 76 and the second light-shielding structure 77 are configured to shield the laser light 62. The first light-shielding structure 76 and the second light-shielding structure 77 can shield at least a portion of the laser light 62. When the light-transmitting member 75 includes the first light-shielding structures 76 and the second light-shielding structures 77, the transmittances of the first and second light-shielding structures 76 and 77 for the laser light 62 are less than the transmittance of the light-transmitting member 75 for the laser light 62. When light-transmitting structures such as holes, etc., are provided in the light-shielding member, the transmittances of the first and second light-shielding structures 76 and 77 for the laser light 62 are less than the transmittance of the light-transmitting structure (e.g., ambient air) for the laser light 62. The transmittances of the first and second light-shielding structures 76 and 77 for the laser light 62 are, for example, 50%. The first light-shielding structure 76 and the second light-shielding structure 77 may be metal films of chrome, etc., or may be dielectric multilayer films.

In the example shown in FIGS. 10 to 12, the transmittance of the first light-shielding structure 76 for the laser light 62 is the same as the transmittance of the second light-shielding structure 77 for the laser light 62. The transmittance of the second light-shielding structure 77 for the laser light 62 may be greater than the transmittance of the first light-shielding structure 76 for the laser light 62. For example, the first light-shielding structure 76 is formed using a material having a first transmittance for the laser light 62; and the second light-shielding structure 77 is formed using a material having a second transmittance for the laser light 62 that is greater than the first transmittance. The transmittance of the second light-shielding structure 77 for the laser light 62 can be set to be greater than the transmittance of the first light-shielding structure 76 for the laser light 62 by forming the first light-shielding structure 76 to have a first thickness and by forming the second light-shielding structure 77 to have a second thickness that is less than the first thickness. The transmittance of the second light-shielding structure 77 for the laser light 62 may be set to be greater than the transmittance of the first light-shielding structure 76 for the laser light 62 by combining the materials and thicknesses described above.

The transmittance of the second light-shielding structure 77 for the laser light 62 may be less than the transmittance of the first light-shielding structure 76 for the laser light 62. For example, the density of the second light-shielding structures 77 in the second area 72 can be sufficiently less than the density of the first light-shielding structures 76 in the first area 71. As a result, even when the transmittance of the second light-shielding structure 77 for the laser light 62 is less than the transmittance of the first light-shielding structure 76 for the laser light 62, the level of the light shielding in the first area 71 can be greater than the level of the light shielding in the second area 72.

In the example shown in FIGS. 10 to 12, the second light-shielding structures 77 are located in the second area 72. However, the second area 72 is not limited thereto; the second light-shielding structures 77 may not be provided in the second area 72. When the second light-shielding structures 77 is not provided in the second area 72, the part of the mask in the second area 72 may include only the light-transmitting member 75, or may include holes extending through the light-transmitting member 75.

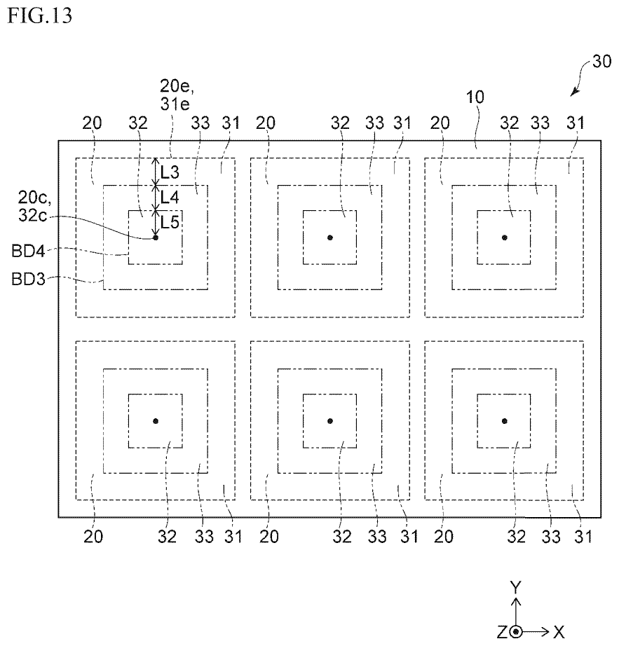

FIG. 13 is a schematic plan view diagram showing a stacked body processed in a method for manufacturing a light-emitting device according to a modification of the embodiment.

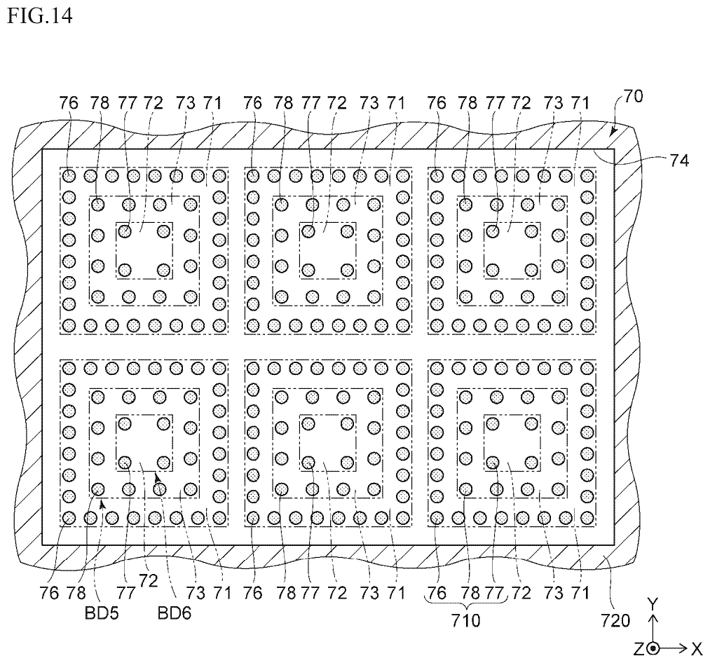

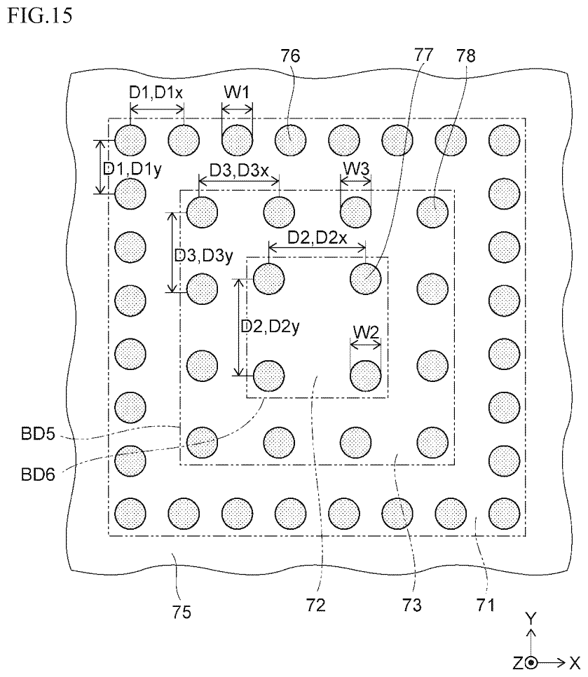

FIG. 14 is a schematic plan view diagram showing a mask used in the method for manufacturing the light-emitting device according to the modification of the embodiment.

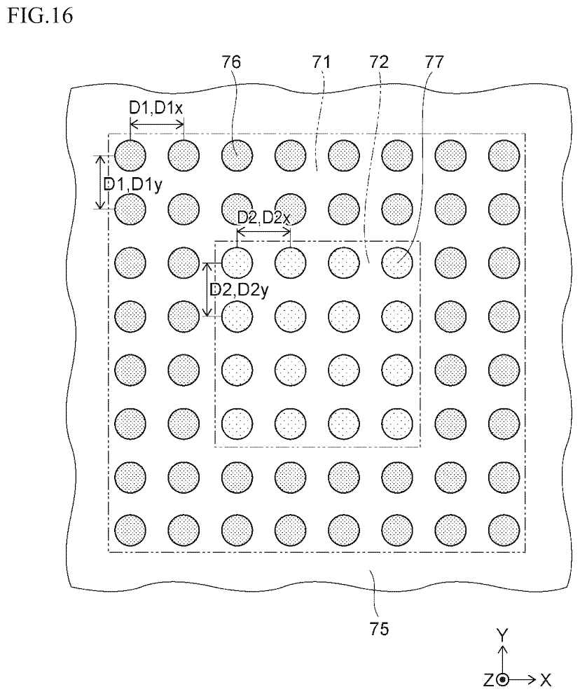

FIG. 15 is a schematic enlarged plan view diagram showing a portion of the mask used in the method for manufacturing the light-emitting device according to the modification of the embodiment.

A part of the mask illustrated in FIG. 14 is enlarged in FIG. 15.

As shown in FIG. 13, the stacked body 30 can further include a plurality of intermediate regions 33, each of which is positioned between the corresponding central region 32 and the corresponding outer perimeter region 31 in the plan view. Hereinafter, the intermediate region 33 may be referred to as a third region. The intermediate region 33 is positioned further inward than the corresponding outer perimeter region 31. The intermediate region 33 is positioned further outward than the corresponding central region 32. The outer perimeter region 31 and the corresponding intermediate region 33 are partitioned by a boundary BD3 which is a virtual line. The intermediate region 33 and the corresponding central region 32 are partitioned by a boundary BD4 which is a virtual line.

In the example shown in FIG. 13, the exterior shape of the outer perimeter region 31 is rectangular in the plan view. Similarly, the exterior shape of the intermediate region 33 (i.e., the exterior shape defined by the boundary BD3 which is a virtual line) and the exterior shape of the central region (i.e., the exterior shape defined by the boundary BD4 which is a virtual line) are rectangular. For example, the boundary BD3 and the boundary BD4 are positioned to trisect the area between the outer perimeter edge 31e of the outer perimeter region 31 and the center 32c of the central region 32. That is, for example, a distance L3 between the boundary BD3 and the outer perimeter edge 31e of the outer perimeter region 31, a distance L4 between the boundary BD3 and the boundary BD4, and a distance L5 between the boundary BD4 and the center 32c of the central region 32 are equal. The distance L3, the distance L4, and the distance L5 may be different from each other. The distance L3 may be less than the distance L4 or greater than the distance L4. The distance L3 may be less than the distance L5 or greater than the distance L5. The distance L4 may be less than the distance L5 or greater than the distance L5.

As shown in FIGS. 14 and 15, the mask 70 can further include a plurality of third areas 73 that correspond to the intermediate regions 33 in the plan views. The first area 71 and the corresponding third area 73 are partitioned by a boundary BD5 which is a virtual line. The second area 72 and the corresponding third area 73 are partitioned by a boundary BD6 which is a virtual line. The third region 73 is located in the mask 70 to overlap the intermediate region 33 in a plan view.

In the example shown in FIGS. 14 and 15, the exterior shape of the first area 71 is rectangular. Similarly, the exterior shape of the second area 72 (i.e., the exterior shape defined by the boundary BD5 which is a virtual line) and the exterior shape of the third area (i.e., the exterior shape defined by the boundary BD6 which is a virtual line) are rectangular.

In the example shown in FIG. 14, the mask 70 includes the inner light-shielding part 710 including the first light-shielding structures 76, the second light-shielding structures 77, and a plurality of third light-shielding structures 78, and the outer light-shielding part 720 including the opening 74. The inner light-shielding part 710 is located inside the opening 74.

In the example shown in FIGS. 13 to 15, the irradiation with the laser light 62 is performed with the same irradiation intensity on the first to third areas 71 to 73 in the separation process. The irradiation intensity of the laser light 62 transmitted through the second area 72 and casted on the central region 32 is set to be greater than the irradiation intensity of the laser light 62 transmitted through the third area 73 and casted on the intermediate region 33; and the irradiation intensity of the laser light 62 transmitted through the third area 73 and casted on the intermediate region 33 is set to be greater than the irradiation intensity of the laser light 62 transmitted through the first area 71 and casted on the outer perimeter region 31.

Specifically, by using the mask 70, the irradiation intensity of the laser light 62 transmitted through the second area 72 and casted on the central region 32 can be set to be greater than the irradiation intensity of the laser light 62 transmitted through the third area 73 and casted on the intermediate region 33 by setting the level of the light shielding in the third area 73 to be greater than the level of the light shielding in the second area 72. The irradiation intensity of the laser light 62 transmitted through the third area 73 and casted on the intermediate region 33 can be set to be greater than the irradiation intensity of the laser light 62 transmitted through the first area 71 and casted on the outer perimeter region 31 by setting the level of the light shielding in the first area 71 to be greater than the level of the light shielding in the third area 73. As a result, the occurrence of delamination defects such as cracks of the semiconductor layer 20 can be reduced.

The mask 70 includes the multiple third light-shielding structures 78 that are positioned in the third area 73 and shield the laser light 62. Examples of the arrangement, size, and shape of the third light-shielding structures 78 may be the same as the examples of the arrangements, sizes, and shapes of the first light-shielding structures 76 and the second light-shielding structures 77 described above; and a description is therefore omitted.

In the example shown in FIGS. 13 to 15, a spacing D3 of the adjacent third light-shielding structures 78 is greater than the spacing D1 and less than the spacing D2. In the example shown in FIGS. 13 to 15, the density of the third light-shielding structures 78 in the third area 73 is less than the density of the first light-shielding structures 76 in the first area 71 and greater than the density of the second light-shielding structures 77 in the second area 72. As a result, the level of the light shielding in the third area 73 can be set to be greater than the level of the light shielding in the second area 72; and the irradiation intensity of the laser light 62 transmitted through the second area 72 and casted on the central region 32 can be set to be greater than the irradiation intensity of the laser light 62 transmitted through the third area 73 and casted on the intermediate region 33. The level of the light shielding in the first area 71 can be set to be greater than the level of the light shielding in the third area 73; and the irradiation intensity of the laser light 62 transmitted through the third area 73 and casted on the intermediate region 33 can be set to be greater than the irradiation intensity of the laser light 62 transmitted through the first area 71 and casted on the outer perimeter region 31.

FIG. 16 is a schematic enlarged plan view diagram showing a portion of a mask used in a method for manufacturing a light-emitting device according to another modification of the embodiment.

In the example shown in FIG. 16, the spacing D2 of the adjacent second light-shielding structures 77 is the same as the spacing D1 of the adjacent first light-shielding structures 76.

In the example shown in FIG. 16, the transmittance of the second light-shielding structure 77 for the laser light 62 is greater than the transmittance of the first light-shielding structure 76 for the laser light 62. As described above, for example, the transmittance of the second light-shielding structure 77 for the laser light 62 can be set to be greater than the transmittance of the first light-shielding structure 76 for the laser light 62 by adjusting the materials and/or thicknesses.

By setting the transmittance of the second light-shielding structure 77 for the laser light 62 to be greater than the transmittance of the first light-shielding structure 76 for the laser light 62, the level of the light shielding in the first area 71 can be set to be greater than the level of the light shielding in the second area 72 even when the spacing D2 of the adjacent second light-shielding structures 77 is the same as the spacing D1 of the adjacent first light-shielding structures 76. As a result, the irradiation intensity of the laser light 62 transmitted through the second area 72 and casted on the central region 32 can be set to be greater than the irradiation intensity of the laser light 62 transmitted through the first area 71 and casted on the outer perimeter region 31.

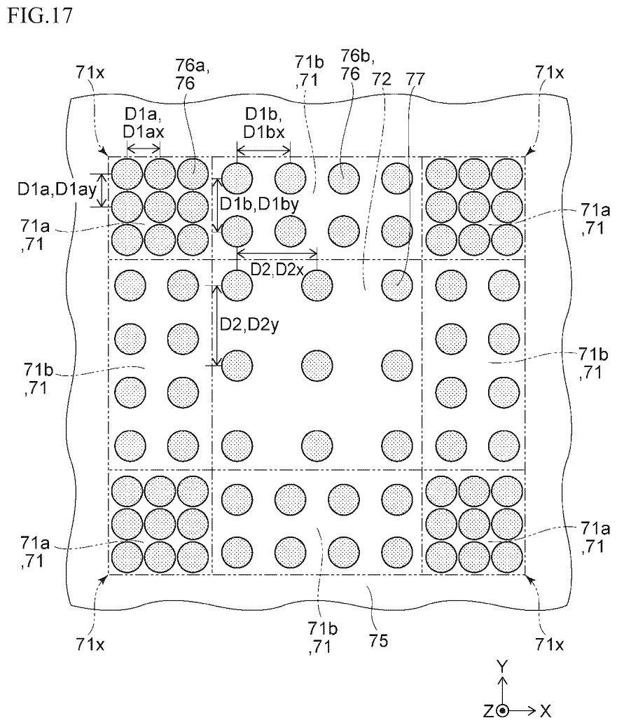

FIG. 17 is a schematic enlarged plan view diagram showing a portion of a mask used in a method for manufacturing a light-emitting device according to another modification of the embodiment.

As shown in FIG. 17, the first area 71 of the mask 70 may include corner areas 71a (may be referred to as fourth areas) that include corners 71x, and side areas 71b that are each positioned between two corner areas 71a. The corner areas 71a are regions partitioned by virtual lines formed by extending the boundary lines between the first area 71 and the second area 72.

In the example shown in FIG. 17, corner light-shielding structures 76a are located in the corner areas 71a; and side light-shielding structures 76b are located in the side area 71b. In the example shown in FIG. 17, the corner light-shielding structures 76a are arranged at uniform spacing (a spacing D1ax) in the X-direction, and are arranged at uniform spacing (a spacing D1ay) in the Y-direction. For example, the average value of the spacings D1ax and D1ay is taken as a spacing D1a of the adjacent corner light-shielding structures 76a. In the example shown in FIG. 17, the side light-shielding structures 76b are arranged at uniform spacing (a spacing D1bx) in the X-direction, and are arranged at uniform spacing (a spacing D1by) in the Y-direction. For example, the average value of the spacings D1bx and D1by is taken as a spacing D1b of the adjacent side light-shielding structures 76b.

In the example shown in FIG. 17, the spacing D1a is less than the spacing D1b. In the example shown in FIG. 17, the density of the corner light-shielding structures 76a in the corner areas 71a is greater than the density of the side light-shielding structures 76b in the side areas 71b. As a result, the level of the light shielding in the corner areas 71a can be set to be greater than the level of the light shielding in the side areas 71b; and the irradiation intensity of the laser light 62 at the positions corresponding to the corner areas 71a of the stacked body 30 can be set to be less than the irradiation intensity of the laser light 62 at the positions corresponding to the side areas 71b of the stacked body 30. As a result, the timing discrepancy between the separation of the outer perimeter region 31 and the separation of the central region can be reduced, and the occurrence of delamination defects such as cracks of the semiconductor layer 20 can be reduced.

In the example shown in FIG. 17, the spacing D1b is less than the spacing D2. In the example shown in FIG. 17, the density of the side light-shielding structures 76b in the side areas 71b is, for example, greater than the density of the second light-shielding structures 77 in the second area 72. As a result, the level of the light shielding in the side areas 71b can be greater than the level of the light shielding in the second area 72; and the irradiation intensity of the laser light 62 at the positions corresponding to the side areas 71b of the stacked body 30 can be set to be less than the irradiation intensity of the laser light 62 at the positions corresponding to the central region 32. As a result, the timing discrepancy between the separation of the outer perimeter region 31 and the separation of the central region can be reduced, and the occurrence of delamination defects such as cracks of the semiconductor layer 20 can be reduced.

In the example above, the light-shielding structure density in the mask 70 decreases in stages for each region from the outer perimeter toward the center of the mask 70. The change of the light-shielding structure density in the mask 70 may have two, three, or more stages. The occurrence of delamination defects can be reduced as the number of stages increases. The light-shielding structure density in the mask 70 may decrease continuously from the outer perimeter toward the center of the mask 70.

### Separation Method

The separation method according to the embodiment includes the preparation process and the separation process according to the method for manufacturing the light-emitting device described above.

More specifically, in the separation method according to the embodiment, the substrate 10 is separated from the semiconductor layer 20 of the stacked body 30 by irradiating with the laser light 62, wherein the stacked body 30 includes the substrate 10 and the semiconductor layer 20 stacked on the substrate 10, and the stacked body 30 includes the outer perimeter region 31 and the central region 32 positioned inward of the outer perimeter region 31 in a plan view. In such a case, the irradiation with the laser light 62 is performed simultaneously on the central region 32 and the outer perimeter region 31. The irradiation intensity of the laser light 62 at the central region 32 is set to be greater than the irradiation intensity of the laser light 62 at the outer perimeter region 31.

The separation method according to the embodiment is applicable to the preparation process and the separation process according to the method for manufacturing the light-emitting device shown in FIGS. 1 to 4 and FIGS. 10 to 16 above.

By setting the irradiation intensity of the laser light 62 at the central region 32 to be greater than the irradiation intensity of the laser light 62 at the outer perimeter region 31, the timing difference between the separation of the outer perimeter region 31 and the separation of the central region 32 can be reduced. As a result, the occurrence of delamination defects such as cracks of the semiconductor layer 20 can be reduced.

1. A method for manufacturing a light-emitting device, comprising:
preparing a stacked body including a substrate and a semiconductor layer on the substrate; and
separating the substrate from the semiconductor layer by irradiating the stacked body with a laser light,
a first region of the stacked body corresponding to an outer perimeter region of the semiconductor layer and a second region of the stacked body corresponding to a center region of the semiconductor layer being simultaneously irradiated with the laser light during said separating,
an irradiation intensity of the laser light at the second region of the stacked body being greater than an irradiation intensity of the laser light at the first region of the stacked body.

2. The method according to claim 1, wherein
said separating includes:
disposing a mask that is light-transmitting and includes a first area and a second area, at a side of the stacked body on which the laser light is incident, the first area corresponding to the first region of the stacked body and the second area corresponding to the second region of the stacked body; and
irradiating the first area and the second area of the mask with the laser light at a same irradiation intensity.

3. The method according to claim 2, wherein the mask includes one or more first light-shielding structures in the first area.

4. The method according to claim 2, wherein the mask includes a plurality of first light-shielding structures in the first area and a plurality of second light-shielding structures in the second area.

5. The method according to claim 4, wherein a density of the first light-shielding structures in the first area of the mask is greater than a density of the second light-shielding structures in the second area of the mask.

6. The method according to claim 4, wherein
the plurality of first light-shielding structures is regularly arranged in a direction in the first area of the mask and the plurality of second light-shielding structures is regularly arranged in the direction in the second area of the mask,
each of the plurality of first light-shielding structures and each of the plurality of second light-shielding structures have a same footprint, and
a distance between centers of adjacent two of the plurality of second light-shielding structures in the direction is greater than a distance between adjacent two of the plurality of first light-shielding structures in the direction.

7. The method according to claim 4, wherein
the mask includes a light-transmitting member including a first surface that is positioned to face the stacked body during said disposing and a second surface opposite to the first surface, and
the plurality of first light-shielding structures and the plurality of second light-shielding structures are disposed on the first surface.

8. The method according to claim 4, wherein a transmittance of the laser light through one of the first light-shielding structures is less than a transmittance of the laser light through one of the second light-shielding structures.

9. The method according to claim 4, wherein a transmittance of the laser light through one of the first light-shielding structures is greater than a transmittance of the laser light through one of the second light-shielding structures.

10. The method according to claim 4, wherein a thickness of the first light-shielding structures is different from a thickness of the second light-shielding structures.

11. The method according to claim 1, wherein
the stacked body includes a plurality of semiconductor layers provided on the substrate and separated from each other, the plurality of semiconductor layers including the semiconductor layer, and
during said separating, a region of the stacked body that corresponds to the plurality of semiconductor layers and includes the first and second regions is irradiated to separate the plurality of semiconductor layers from the substrate.

12. The method according to claim 1, wherein
during said separating, a third region of the stacked body between the first region and the second region of the stacked body is irradiated with the laser light simultaneously with the first and second regions, and
an irradiation intensity of the laser light at the third region is greater than the irradiation intensity of the laser light at the first region and less than the irradiation intensity of the laser light at the second region.

13. The method according to claim 12, wherein
said separating includes:
disposing a mask that is light-transmitting and includes a first area, a second area, and a third area, at a side of the stacked body on which the laser light is incident, the first, second, and third areas corresponding to the first, second, and third regions of the stacked body, respectively; and
irradiating the first, second, and third areas of the mask with the laser light at a same irradiation intensity.

14. The method according to claim 13, wherein
the mask includes a plurality of first light-shielding structures in the first area, a plurality of second light-shielding structures in the second area, and a plurality of third light-shielding structured in the third area, and
a density of the third light-shielding structures in the third area of the mask is greater than a density of the second light-shielding structures in the second area of the mask, and less than a density of the first light-shielding structures in the first area of the mask.

15. The method according to claim 1, wherein
during said separating, a fourth region of the stacked body corresponding to a corner region of the semiconductor layer is irradiated with the laser light simultaneously with the first and second regions, and
an irradiation intensity of the laser light at the fourth region is less than the irradiation intensity of the laser light at the first region.

16. The method according to claim 15, wherein
said separating includes:
disposing a mask that is light-transmitting and includes a first area, a second area, and a fourth area, at a side of the stacked body on which the laser light is incident, the first, second, and fourth areas corresponding to the first, second, and fourth regions of the stacked body, respectively; and
irradiating the first, second, and fourth areas of the mask with the laser light at a same irradiation intensity.

17. The method according to claim 16, wherein
the mask includes a plurality of first light-shielding structures in the first area, a plurality of second light-shielding structures in the second area, and a plurality of fourth light-shielding structured in the fourth area,
a density of the first light-shielding structures in the first area of the mask is greater than a density of the second light-shielding structures in the second area of the mask, and
a density of the fourth light-shielding structures in the fourth area of the mask is greater than the density of the first light-shielding structures in the first area of the mask.

18. The method according to claim 1, further comprising:
after said separating, mounting the semiconductor layer to a wiring substrate, so that a surface of the semiconductor layer that is opposite to a surface of the semiconductor layer separated from the substrate faces an upper surface of the wiring substrate.

19. A separation method of a stacked body including a substrate and a semiconductor layer on the substrate, comprising:
separating the substrate from the semiconductor layer by irradiating the stacked body with a laser light,
a first region of the stacked body corresponding to an outer perimeter region of the semiconductor layer and a second region of the stacked body corresponding to a center region of the semiconductor layer being simultaneously irradiated with the laser light during said separating,
an irradiation intensity of the laser light at the second region of the stacked body being greater than an irradiation intensity of the laser light at the first region of the stacked body.
